(19) United States
(12) Patent Application Publication
(10) Pub. No.: US 2009/0041075 A1
(43) Pub. Date: Feb. 12, 2009

(54) Surface-emitting type semiconductor optial device and method for manufacturing a surface-emitting type semiconductor optical device

(76) Inventor: Jun-ichi Hashimoto, Yokohama-shi (JP)

Correspondence Address: SMITH, GAMBRELL & RUSSELL, 1130 CONNECTICUT AVENUE, N.W., SUITE 1130, WASHINGTON, DC, 20036, US

(21) Appl. No.: 12/222,065

(22) Filed: Jul. 31, 2008

(30) Foreign Application Priority Data
Aug. 3, 2007 (JP) P2007-203476

(51) Int. Cl. H01S 5/00; H01L 21/02

(52) U.S. Cl. 372/45.01; 438/39; 257/E21.002

(57) ABSTRACT

A surface-emitting type semiconductor optical device includes: a first DBR portion of a first conductivity type provided on a GaAs substrate of the first conductivity type; an active layer provided on the first DBR portion; a second DBR portion provided on the active layer; a mesa-shaped conductive layer, which is provided between the first DBR portion and the second DBR portion, and which has, embedded therein, a current confinement portion for supplying current to the active layer; and a burying layer comprising single undoped GaInP and provided between the first DBR portion and the second DBR portion, on the side faces of the conductive layer. The resistivity of the undoped GaInP in the surface-emitting type semiconductor optical device is not lower than 10⁵ Ωcm. Improved productivity, as well as favorable device characteristics and high reliability can be achieved as a result.

### BACKGROUND OF THE INVENTION

1. Field of the Invention

The present invention relates to a surface-emitting type semiconductor optical device, and to a method for manufacturing a surface-emitting type semiconductor optical device.

2. Related Background Art

Surface-emitting semiconductor lasers (hereinafter, also VCSEL: vertical cavity surface emitting lasers) hold great potential for extensive use as small, low power-consumption and low-cost lasers, in optical communications, optical recording, optical information processing and the like. Ordinarily, VCSELs must be capable of high-speed modulation up to, for instance, 10 Gbps. To that end, there are widely employed structures in which parasitic capacitance of a device is reduced by burying a central light-emitting region in a high-resistivity insulating layer (burying layer). Known such VCSEL structures encompass also structures in which there is provided a current confinement portion separately from the above-described high-resistivity burying layer. A current confinement portion provided separately entails a structure that is more complex than when a same structure serves both as the high-resistivity burying layer and the current confinement portion. However, employing different structures for current confinement and for parasitic capacitance reduction enables the structures to be optimized independently, which increases the degree of freedom in design, and makes it easier to optimize device characteristics. Examples of such structures are proposed in, for instance, Hitoshi Shimizu, et. al., “1.3-μm-Range GaInNAsSb-GaAs VCSELs”, IEEE J. Select. Topics Quantum Electron, Vol. 9, No. 5, pp 1214-1219, 2003 and Japanese Patent Application Laid-open No. 2006-196880. In these structures, selective oxidation of a semiconductor layer comprising Al is used for current confinement, while dielectric insulating layers of, for instance, BCB or polyimide are used in high-resistivity burying layers for capacitance reduction.

However, the difference between the coefficient of thermal expansion of a semiconductor and that of a dielectric insulating layer of BCB or polyimide is substantial. When a dielectric insulating layer is used in the burying layer, therefore, the semiconductor layers in the light-emitting region are subjected to excessive stress during temperature fluctuations. The thermal resistance of dielectric insulating layers is ordinarily higher than that of semiconductors, and hence using a dielectric insulating layer in the burying layer is likely to impair heat dissipation in the device. The above-mentioned stress and poorer heat dissipation impair in turn the characteristics and reliability of the device. Moreover, the difference between the coefficients of thermal expansion of semiconductors and dielectric insulating layers is substantial, as described above. This impairs adherence between dielectric insulating layers and adjacent semiconductor layers, increasing the likelihood of delamination, which in turn gives rise to the problem of poorer manufacturing yields and lower productivity.

### SUMMARY OF THE INVENTION

In light of the foregoing, it is an object of the present invention to provide a surface-emitting type semiconductor optical device, and a method for manufacturing a surface-emitting device, that allow increasing productivity and realizing good device characteristics and high reliability.

As a result of diligent research directed at attaining the above goal, the inventors perfected the present invention upon finding that, by being grown at low temperature, for instance by organometallic vapor phase epitaxy, undoped GaInP can be used as a burying layer, for reducing device parasitic capacitance, such that high resistivity to both electrons and holes can be realized in the burying layer.

Specifically, a first aspect of the present invention relates to a method for manufacturing a surface-emitting type semiconductor optical device. The method for manufacturing a surface-emitting type semiconductor optical device comprises a first step of forming a first DBR portion of a first conductivity type on a GaAs substrate of the first conductivity type; a second step of forming an active layer on the first DBR portion, and forming a mesa-shaped first semiconductor layer on the active layer; a third step of forming a burying layer formed of a single material, by growing undoped GaInP at a region where the first semiconductor layer is not formed on the first DBR portion; and a fourth step of forming a second DBR portion on the first semiconductor layer, after formation of the burying layer. A current confinement portion for supplying current to the active layer is embedded in the first semiconductor layer. The burying layer is formed by growing the undoped GaInP at a growth temperature ranging from 500° C. to 600° C.

In the above manufacturing method, the burying layer is formed by growing undoped GaInP at the above-described growth temperature, as a result of which the resistivity of the burying layer is not lower than 10⁵ Ωcm. Device capacitance can be considerably reduced thereby. Also, there is provided a current confinement portion separately from the burying layer for reducing device parasitic capacitance, and hence the structure of current confinement and the structure for reducing device parasitic capacitance can be optimized independently. Moreover, the above burying layer can trap both electrons and holes, and hence functions as a burying layer for both p-type and n-type regions. This increases the degree of freedom in design, and makes it easier to optimize device characteristics. The burying layer comprises an undoped GaInP semiconductor layer, and hence there arise virtually no differences between the coefficients of thermal expansion of the burying layer and other semiconductor layers, such as the first semiconductor layer, comprised in the surface-emitting type semiconductor optical device. Moreover, the burying layer comprises the above-described semiconductor, which improves the heat dissipation ability of the burying layer. There occur therefore no excessive stress in the device, derived from differences between the coefficient of thermal expansion of the burying layer and other layers adjacent thereto, and no impairment of device characteristics and/or reliability on account of insufficient heat dissipation by a burying layer. This allows thus realizing good device characteristics and reliability. The burying layer can trap both electrons and holes, and hence there is no need for providing, for instance, a separate hole trapping layer. The increase in device capacitance that accompanies the addition of, for instance, a hole trapping layer, can be avoided as a result, which affords a faster operation.

The burying layer comprises a semiconductor having a coefficient of thermal expansion similar to that of the adjacent semiconductor layers. Therefore, there occurs no problem of insufficient adherence of the burying layer to adjacent layers, caused by differences in the coefficient of thermal expansion vis-à-vis adjacent layers when the burying layer uses a dielectric material, which is different from a semiconductor. The productivity of the surface-emitting type semiconductor optical device can be enhanced as a result. The burying layer, moreover, is undoped, and hence there occurs no interdiffusion between impurities in the burying layer and impurities in the adjacent layers, during growth and/or processing, as is the case when the burying layer is doped with impurities. Accordingly, characteristics and high speed do not become impaired, which is a serious problem caused by a lowering of the resistivity of the burying layer and an increase in the resistivity of adjacent layers, brought about by interdiffusion, when using a semiconductor burying layer having had the resistivity thereof increased through doping with impurities. The burying layer, moreover, is undoped, and hence there is no need for, for instance, preparing a dopant raw material and setting doping conditions. The productivity of the surface-emitting type semiconductor optical device can be enhanced as a result.

In the method for manufacturing a surface-emitting type semiconductor optical device according to the present invention, preferably, the resistivity of the undoped GaInP is not lower than 10⁵ Ωcm for a 5 V forward voltage across the surface-emitting type semiconductor optical device.

In the second step of the method for manufacturing a surface-emitting type semiconductor optical device according to the present invention, preferably, the mesa-shaped first semiconductor layer is formed by forming the current confinement portion on a predetermined region within a first region on the surface of the active layer, embedding the current confinement portion by growing a first layer that is to become the first semiconductor layer, on the surface of the active layer and on the current confinement portion, and by etching, within the first layer, a portion positioned on a second region that is adjacent to the first region on the surface of the active layer; while in the third step, the burying layer is formed by growing the undoped GaInP on the second region on the surface of the active layer.

In the method for manufacturing a surface-emitting type semiconductor optical device according to the present invention, furthermore, the current confinement portion is preferably formed after forming a first interlayer on the active layer.

In the method for manufacturing a surface-emitting type semiconductor optical device according to the present invention, furthermore, the current confinement portion is preferably a tunnel junction obtained by layering a second semiconductor layer and a third semiconductor layer of mutually different conductivity types; the current confinement portion is formed by sequentially growing, on the active layer, a second layer that is to become the second semiconductor layer, and a third layer that is to become the third semiconductor layer, and by etching, within the second layer and the third layer, a portion other than the predetermined region; and the first interlayer is a layer for stopping etching, for forming the current confinement portion.

Herein, the shape of the current confinement portion can be achieved with good reproducibility and in-plane uniformity. As a result, characteristics of the surface-emitting type semiconductor optical device can be achieved as well with good reproducibility and uniformity.

In the second step of the method for manufacturing a surface-emitting type semiconductor optical device according to the present invention, preferably, the mesa-shaped active layer and the first semiconductor layer are formed: by forming the current confinement portion on a predetermined region in the first region on the surface of the active layer; by embedding the current confinement portion by growing a first layer that is to become the first semiconductor layer, on the surface of the active layer and on the current confinement portion; and by etching, within the first layer, a portion positioned on a second region that is adjacent to the first region on the surface of the active layer, and etching, within the active layer, a portion outward of the first region and having the second region; while in the third step, the burying layer is formed by growing the undoped GaInP on a region where the mesa-shaped active layer and the first semiconductor layer are not formed within the surface of the first DBR portion.

In the second step of the method for manufacturing a surface-emitting type semiconductor optical device according to the present invention, preferably, a second interlayer for stopping the etching is formed on the first DBR portion, whereafter the active layer is formed on the second interlayer.

Herein, the shape of the light-emitting region comprising the active layer can be achieved with good reproducibility and in-plane uniformity. As a result, characteristics of the surface-emitting type semiconductor optical device can be achieved as well with good reproducibility and uniformity.

In the method for manufacturing a surface-emitting type semiconductor optical device according to the present invention, preferably, the current confinement portion is a tunnel junction obtained by layering a second semiconductor layer and a third semiconductor layer of mutually different conductivity types; and the current confinement portion is formed by sequentially growing, on the active layer, a second layer that is to become the second semiconductor layer, and a third layer that is to become the third semiconductor layer, and by etching, within the second layer and the third layer, a portion other than the predetermined region.

In the method for manufacturing a surface-emitting type semiconductor optical device according to the present invention, preferably, the burying layer is formed by growing the undoped GaInP at a growth temperature ranging from 500° C. to 550° C.

Another aspect of the present invention relates to a surface-emitting type semiconductor optical device. The surface-emitting type semiconductor optical device comprises a first DBR portion of a first conductivity type provided on a GaAs substrate of the first conductivity type; an active layer provided on the first DBR portion; a second DBR portion provided on the active layer; a mesa-shaped first semiconductor layer, which is provided between the first DBR portion and the second DBR portion, and which has, embedded therein, a current confinement portion for supplying current to the active layer; and a burying layer, comprising single undoped GaInP, provided between the first DBR portion and the second DBR portion, on the side faces of the first semiconductor layer; wherein the resistivity of the undoped GaInP is not lower than 10⁵ Ωcm.

In such a constitution, the resistivity of the burying layer is not lower than 10⁵ Ωcm, whereby device capacitance can be considerably reduced. The above constitution, moreover, comprises a current confinement portion separate from the burying layer for reducing parasitic capacitance in the device. As a result, the structure for current confinement and the structure for reducing device parasitic capacitance can be optimized independently. Also, the above burying layer can trap both electrons and holes, and hence functions as a burying layer for both p-type and n-type regions. This increases the degree of freedom in design, and makes it easier to optimize device characteristics. The burying layer comprises an undoped GaInP semiconductor layer, and hence there arise virtually no differences between the coefficients of thermal expansion of the burying layer and other semiconductor layers, such as the first semiconductor layer, comprised in the surface-emitting type semiconductor optical device. Moreover, the burying layer comprises a semiconductor as described above, which improves the heat dissipation ability of the burying layer. There occur therefore no excessive stress in the device, derived from differences between the coefficient of thermal expansion of the burying layer and other layers adjacent thereto, and no impairment of device characteristics and/or reliability on account of insufficient heat dissipation by the burying layer. This allows thus realizing good device characteristics and reliability. The burying layer can trap both electrons and holes, and hence there is no need for providing, for instance, a separate hole trapping layer. This allows avoiding, as a result, the increase in device capacitance that accompanies the addition of, for instance, a hole trapping layer. A faster operation is thus afforded thereby.

The burying layer comprises a semiconductor having a coefficient of thermal expansion similar to that of the adjacent semiconductor layers. Therefore, there occurs no problem of insufficient adherence of the burying layer with adjacent layers, caused by differences in the coefficient of thermal expansion vis-à-vis adjacent layers when the burying layer uses a dielectric material, which is different from a semiconductor. The productivity of the surface-emitting type semiconductor optical device can be enhanced as a result. The burying layer, moreover, is undoped, and hence there occurs no interdiffusion between impurities in the burying layer and impurities in the adjacent layers, during growth and/or processing, as is the case when the burying layer is doped with impurities. Accordingly, characteristics and high speed do not become impaired, which is a serious problem caused by a lowering of the resistivity of the burying layer and an increase in the resistivity of adjacent layers, brought about by interdiffusion, when using a semiconductor burying layer having had the resistivity thereof increased through doping with impurities. The burying layer, moreover, is undoped, and hence there is no need for, for instance, preparing a dopant raw material and setting doping conditions. The productivity of the surface-emitting type semiconductor optical device can be enhanced as a result.

In the surface-emitting type semiconductor optical device according to the present invention, preferably, the resistivity of the undoped GaInP is not lower than 10⁵ Ωcm for a 5 V forward voltage across the surface-emitting type semiconductor optical device.

Preferably, the first semiconductor layer and the burying layer are disposed between the active layer and the second DBR portion, or between the active layer and the first DBR portion.

Herein, no burying layer is provided in the second DBR portion, and hence the second DBR portion can be grown without discontinuing growth. Therefore, controllability of the reflectivity of the second DBR portion is not impaired, while no crystal degradation occurs in the second DBR portion.

Preferably, the surface-emitting type semiconductor optical device further comprises a first interlayer provided between the current confinement portion and the active layer.

Herein, the first interlayer can function as an etching stop layer when, for instance, the current confinement portion is formed by etching. As a result, the shape of the current confinement portion can be achieved with good reproducibility and in-plane uniformity. As a result, characteristics of the surface-emitting type semiconductor optical device can be achieved as well with good reproducibility and uniformity.

Preferably, the burying layer is provided on the side faces of the active layer.

In this case, the burying layer can be made thicker, and hence a surface-emitting type semiconductor optical device can be obtained thereby that has reduced device capacitance and that is capable of operating at higher speed. The refractive index of the burying layer comprising GaInP is ordinarily lower than the refractive index of the active layer. Light becomes strongly confined thus in the active layer on account of that refractive index difference. Since light can be strongly confined in the active layer, there can be obtained a surface-emitting type semiconductor laser having efficient stimulated emission and significantly improved oscillation characteristics.

Preferably, the surface-emitting type semiconductor optical device further comprises a second interlayer provided between the first DBR portion and the active layer.

Herein, the second interlayer can function as an etching stop layer during formation by etching of the light-emitting region comprising the active layer. As a result, the shape of the light-emitting region comprising the active layer can be achieved with good reproducibility and in-plane uniformity, and in consequence, characteristics of the surface-emitting type semiconductor optical device can be achieved as well with good reproducibility and uniformity.

In the surface-emitting type semiconductor optical device according to the present invention, preferably, the current confinement portion is a tunnel junction obtained by layering a second semiconductor layer and a third semiconductor layer of mutually different conductivity types.

In the method for manufacturing a surface-emitting type semiconductor optical device according to the present invention, and in the surface-emitting type semiconductor optical device according to the present invention, the active layer comprises preferably a III-V compound semiconductor material comprising Ga, As and N.

In the method for manufacturing a surface-emitting type semiconductor optical device according to the present invention, and in the surface-emitting type semiconductor optical device according to the present invention, the active layer comprises preferably any among GaInNAs, GaNAs, GaInNAsP, GaNAsP, GaInNAsSb, GaInNAsSbP, GaNAsSbP and GaNAsSb.

The present invention will be more fully understood from the detailed description given hereinbelow and the accompanying drawings, which are given by way of illustration only and are not to be considered as limiting the present invention.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will be apparent to those skilled in the art from this detailed description.

### BRIEF DESCRIPTION OF THE DRAWINGS

FIG. 1 is a cross-sectional diagram illustrating schematically a surface-emitting type semiconductor optical device according to a first embodiment;

FIG. 2 is a cross-sectional diagram illustrating schematically a measurement sample for verifying resistivity increase in GaInP on account of low-temperature growth;

FIG. 3 is a graph illustrating the relationship between resistivity and applied voltage in a sample comprising undoped GaInP grown at 500° C. or undoped GaInP grown at 550° C.;

FIG. 4 is a set of cross-sectional diagrams illustrating steps of a method for manufacturing the surface-emitting type semiconductor optical device according to the first embodiment;

FIG. 5 is a set of cross-sectional diagrams illustrating steps of a method for manufacturing the surface-emitting type semiconductor optical device according to the first embodiment;

FIG. 6 is a cross-sectional diagram illustrating schematically a surface-emitting type semiconductor optical device according to a second embodiment;

FIG. 7 is a cross-sectional diagram illustrating schematically a surface-emitting type semiconductor optical device according to a third embodiment;

FIG. 8 is a cross-sectional diagram illustrating schematically a surface-emitting type semiconductor optical device according to a fourth embodiment;

FIG. 9 is a set of cross-sectional diagrams illustrating steps of a method for manufacturing the surface-emitting type semiconductor optical device according to the fourth embodiment;

FIG. 10 is a cross-sectional diagram illustrating schematically a surface-emitting type semiconductor optical device according to a fifth embodiment; and

FIG. 11 is a cross-sectional diagram illustrating schematically a surface-emitting type semiconductor optical device according to a sixth embodiment.

### DESCRIPTION OF THE PREFERRED EMBODIMENTS

Embodiments of the present invention are explained next with reference to accompanying drawings. In the drawings, identical elements are denoted with identical reference numerals, and recurrent explanations thereof are omitted. Also, the dimensional ratios in the drawings do not necessarily match those in the explanation.

### First Embodiment

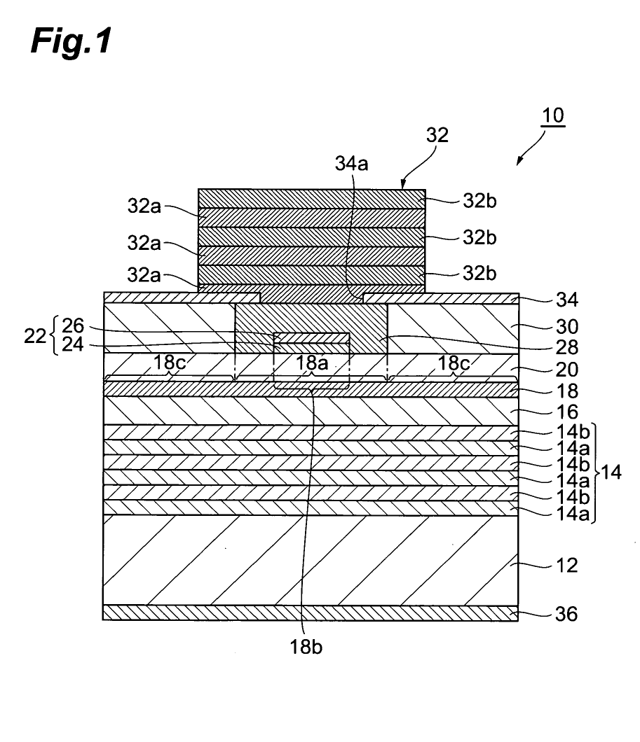

FIG. 1 is a cross-sectional diagram illustrating schematically a surface-emitting type semiconductor optical device according to a first embodiment. The surface-emitting type semiconductor optical device 10 illustrated in FIG. 1 is, for instance, a surface emitting semiconductor laser (VCSEL).

The surface-emitting type semiconductor optical device 10 comprises a first DBR portion 14 (distributed Bragg reflector) of a first conductivity type (for instance, n-type) provided on a GaAs substrate 12 of the first conductivity type; an active layer 18 provided on the first DBR portion 14; a conductive layer (first semiconductor layer) 28, as a mesa-shaped semiconductor layer of a first conductivity type, provided on the first DBR portion 14, and having embedded therein a tunnel junction 22 as a current confinement portion for injecting current into the active layer 18; a second DBR portion 32 provided on the conductive layer 28; and a burying layer 30 provided between the first DBR portion 14 and the second DBR portion 32. The tunnel junction 22 and the conductive layer 28 that covers the tunnel junction 22 constitute a mesa portion since the conductive layer 28 is shaped as a mesa. The burying layer 30, in which the conductive layer 28 is buried, comprises undoped GaInP.

In the present embodiment, the conductive layer 28 and the burying layer 30 are disposed between the active layer 18 and the second DBR portion 32. The conductive layer 28 is provided on a first region 18a on the surface of the active layer 18. The tunnel junction 22 is provided on a portion 18b within the first region 18a. The tunnel junction 22 comprises a heavily doped semiconductor layer (second semiconductor layer) 24 of a second conductivity type (herein, for instance, p-type) provided on the portion 18b, and layered thereon, a heavily doped semiconductor layer (third semiconductor layer) 26 of the first conductivity type. The burying layer 30 is provided on a second region 18c that surrounds the first region 18a on the surface of the active layer 18.

A spacer layer 16 of the first conductivity type is provided between the first DBR portion 14 and the active layer 18. A spacer layer 20 of the second conductivity type is provided between the active layer 18 and the tunnel junction 22. The spacer layers have the function of confining carriers in the active layer. The spacer layers 16, 20 may be omitted in the build-up of the surface-emitting type semiconductor optical device 10. An electrode 34, electrically connected to the conductive layer 28, is provided on the surface of the conductive layer 28 and the burying layer 30. The electrode 34 has an opening 34a through which light from the active layer 18 is emitted. The opening 34a is formed in the electrode 34, at a first region on the surface of the conductive layer 28. The first region on the surface of the conductive layer 28 comprises a region positioned above the tunnel junction 22. The second DBR portion 32 is provided on the first region on the surface of the conductive layer 28. An electrode 36 is formed on the reverse face of the GaAs substrate 12, the electrode 36 being electrically connected to the GaAs substrate 12.

The first DBR portion 14 comprises a plurality of semiconductor layers 14a, 14b that are alternately layered on the GaAs substrate 12. As the first DBR portion 14 there is ordinarily used a multilayer film obtained by alternately layering thin films comprising two materials that have significantly different refractive indices and that are transparent to an oscillation wavelength. Examples of such multilayer films include, for instance, stacks comprising 30 to 40 alternating n-type AlAs layers or n-type AlGaAs layers (semiconductor layers 14a), and n-type GaAs layers (semiconductor layers 14b). Such multilayer films have high reflectivity, for instance not less than 99.9%, to an oscillation wavelength. Preferably, in particular, the thickness of each layer is λ/(4n), wherein λ is the oscillation wavelength, and n is the effective refractive index of the layers (14a, 14b). Such thin films are called quarter-wave (λ/4) films. The reflectivity of the first DBR portion 14 can be effectively increased as a result. In FIG. 1, the first DBR portion 14 is illustrated schematically, and hence the number of layers in the explanation need not necessarily match the number of layers in the figure. The same applies to other figures.

The first DBR portion 14 and the second DBR portion 32, having high reflectivity, constitute a resonator. Light emitted by the active layer 18 oscillates through multiple reflection and amplification at the first DBR portion 14 and the second DBR portion 32. The total sum of the optical thicknesses of the spacer layer 16, the active layer 18, the spacer layer 20, the tunnel junction 22, and the portion of the conductive layer 28 on the tunnel junction 22 (calculated herein as (physical thickness)×(effective refractive index) for each layer, and summated then for all layers) is preferably set beforehand so as to be an integral multiple of the oscillation wavelength λ. In that case, light having a wavelength λ is selectively amplified within the resonator, so that the oscillating light has a wavelength λ.

Preferably, the active layer 18 is a III-V compound semiconductor material comprising Ga, As and N. The active layer 18 enables then oscillation in the 1.3 to 1.6 μm wavelength band, which is suitable for optical communications. As the active layer 18 there can be used, for instance, an active layer having a double quantum well structure comprising an undoped GaInNAs quantum well layer and an undoped GaAs barrier layer. The structure of the active layer 18, however, is not limited thereto, and may be a quantum well structure having a different number of quantum wells (for instance, a single quantum well structure), or a bulk structure.

The active layer 18 may comprise a semiconductor material of GaNAs, or of GaNAs or GaInNAs having added thereto at least Sb and/or P. Sb, which functions as a so-called surfactant, inhibits the three-dimensional growth of GaNAs or GaInNAs. This improves as a result the crystallinity of GaNAs or GaInNAs. P improves crystallinity and reliability by reducing local crystal strain in GaNAs or GaInNAs, and contributes, for instance, to increasing the amount of N uptake in the crystal during growth of GaNAs or GaInNAs.

Specifically, the active layer 18 can comprise a semiconductor material such as, for instance, GaNAsP, GaInNAsP, GaNAsSb, GaInNAsSb, GaNAsSbP, GaInNAsSbP or the like. The lattice constants of these III-V compound semiconductor materials comprising Ga, As and N can be set to have values identical or close to the lattice constant of GaAs. This affords as a result good crystal growth on the GaAs substrate 12. The bandgap energy of these semiconductor materials corresponds to a photoluminescence wavelength of 1 μm or greater. Therefore, using an active layer 18 comprising such semiconductor materials allows realizing easily oscillation wavelengths in a long-wavelength band of 1 μm or longer. Using an active layer 18 comprising these semiconductor materials, therefore, allows obtaining a surface-emitting type semiconductor optical device 10 with an oscillation wavelength in a long-wavelength band of, for instance, 1 to 1.6 μm.

Preferably, the spacer layers 16, 20 comprise a material having a bandgap energy higher than that of the active layer 18. Carriers (electrons and holes) can be confined as a result in the active layer 18. Examples of the material of the spacer layers 16, 20, include, for instance, materials having high bandgap energies and capable of lattice matching with GaAs, such as GaAs, AlGaAs, GaInAsP, GaInP, and AlGaInP. When a desired oscillation characteristic can be obtained without spacer layers, the spacer layers can be omitted in the build-up of the surface-emitting type semiconductor optical device.

The conductive layer 28 of first conductivity type is a layer for ensuring electric conduction between the electrode 34 and the tunnel junction 22. The material of the conductive layer 28 may be, for instance, a material that can be used in the spacer layers.

The semiconductor layers 24, 26 that make up the tunnel junction 22 comprise preferably a low-bandgap material such as GaAs or GaInAs, since doing so further reduces device resistance, on account of the fact the lower the semiconductor bandgap is, the higher the tunneling probability is. The tunnel junction 22, comprising the heavily doped semiconductor layers 24, 26, has the function of confining current. This feature is explained next.

In the configuration illustrated in FIG. 1, when voltage is applied so as to bring the electrode 34 into a high potential, the p-n junctions other than the tunnel junction 22 are simply p-n reverse-bias junctions, and hence current cannot flow. At the heavily doped tunnel junction 22, however, carriers can move across the tunnel junction 22, thanks to tunnel effects, whereupon current can flow. As a result, current can only flow in the tunnel junction 22, which elicits thereby current confinement.

Herein, the shape and size of the current injection region in the surface-emitting type semiconductor optical device 10 is determined by the tunnel junction 22. Accordingly, the shape (for instance, circular, square) and dimensions (diameters or sides, ordinarily of about several μm) of the tunnel junction 22, at a plane substantially perpendicular to the layering direction of the semiconductor layers 24, 26, are appropriately set so as to yield desired device characteristics. Compared to other current confinement methods, tunnel junctions allow significantly reducing device resistance in the current confinement portion. Therefore, a tunnel junction is an advantageous structure for increasing the output and/or the speed of the surface-emitting type semiconductor optical device 10.

The burying layer 30 comprises single undoped GaInP that exhibits high resistivity to electrons and holes. As described below, the burying layer 30 is suitably formed by low-temperature growth using organometallic vapor phase epitaxy (OMVPE). The burying layer 30 has high resistivity, and hence has the function of reducing parasitic capacitance in the device. The resistivity of the burying layer 30 is not lower than 10⁵ Ωcm, at least within the operating voltage of the surface-emitting type semiconductor optical device 10. That is because with such a resistivity, the burying layer 30 exhibits sufficient insulating properties, which allows as a result reducing considerably device capacitance.

Normally, the higher the bandgap of III-V compound semiconductors is, the lower the refractive index thereof becomes. Therefore, the burying layer 30 uses preferably a semiconductor having a bandgap energy that is higher than that of the conductive layer 28. In this case, the conductive layer 28 has a higher refractive index than the burying layer 30, and hence refractive index is higher in the light-emitting region in which the central tunnel junction 22 is existed than in the region where the burying layer 30 is present. This reinforces, therefore, confinement of light in the light-emitting region. As a result, stimulated emission takes place efficiently in the active layer 18, and thus oscillation characteristics can be improved. Oscillation, though, is also possible even when the above conditions are not satisfied. Undoped GaInP, which constitutes the burying layer 30 comprising a single material, has a high bandgap energy (1.9 eV or higher), and hence tends to exhibit a low refractive index. As a result, the refractive index of the conductive layer 28 can be easily made higher than the refractive index of the burying layer 30. This reinforces thus confinement of light in the light-emitting region, and allows easily improving device characteristics.

The second DBR portion 32 comprises a plurality of DBR layers 32a, 32b that are alternately layered on the conductive layer 28. As the second DBR portion 32 there is ordinarily used a multilayer film obtained by alternately layering thin films comprising two materials that have significantly different refractive indices and that are transparent to an oscillation wavelength The second DBR portion 32 comprises, for instance, a semiconductor material or a dielectric material. The second DBR portion 32 may be, for instance, a combination of dielectric films such as TiO₂/SiO₂, a-Si/SiO₂, or a combination of semiconductor films such as AlAs/GaAs or AlGaAs/GaAs. When the second DBR portion 32 comprises, for instance, TiO₂/SiO₂, the dielectric films are layered in, for instance, about 7 pairs. A so-called quarter-wave (λ/4) film is also preferably used in the multilayer film employed in the second DBR portion 32, with a view to obtaining high reflectivity. In FIG. 1, the second DBR portion 32 is illustrated schematically, and hence the number of layers in the explanation need not necessarily match the number of layers in the figure. The same applies to other figures.

In the build-up illustrated in FIG. 1, the opening 34a formed in the electrode 34 is filled with a DBR layer 32a comprised in the second DBR portion 32, but that need not necessarily be the case. For instance, the opening 34a may be filled with a DBR layer 32b, or with both a DBR layer 32a and a DBR layer 32b, or with a layer comprising another material. Preferably, however, the opening 34a is filled with a layer comprising a material that is transparent to the oscillation wavelength, with a view to avoiding absorption of emission light.

Growing a high-planarity second DBR portion 32 is difficult when the region of the base on which the second DBR portion 32 is provided is uneven. As a result, it becomes difficult to form the second DBR portion 32 as designed, and hence the reflectivity of the second DBR portion 32 becomes likewise difficult to control. Preferably, therefore, the surfaces of the conductive layer 28 and of the burying layer 30 are flat, as in the present embodiment. In that case the surface of the electrode 34 and the first region of the surface of the conductive layer 28 are also flat, and thus the second DBR portion 32 can be formed as designed, whereby DBR reflectivity can be easily controlled to a desired value. A second DBR portion 32 having uniform reflectivity and excellent reproducibility is obtained as a result.

The high-resistivity GaInP used in the burying layer 30 of the surface-emitting type semiconductor optical device 10 having the above configuration can be achieved by growing undoped GaInP at a low temperature, for instance, not higher than 600° C. When growth is carried out at such low temperatures, deep-level defects in the bandgap are formed in GaInP.

Such deep levels act as carrier trapping centers that hinder the movement of carriers (electrons and holes) by trapping the carriers. Undoped GaInP thus grown exhibits thereby high resistance.

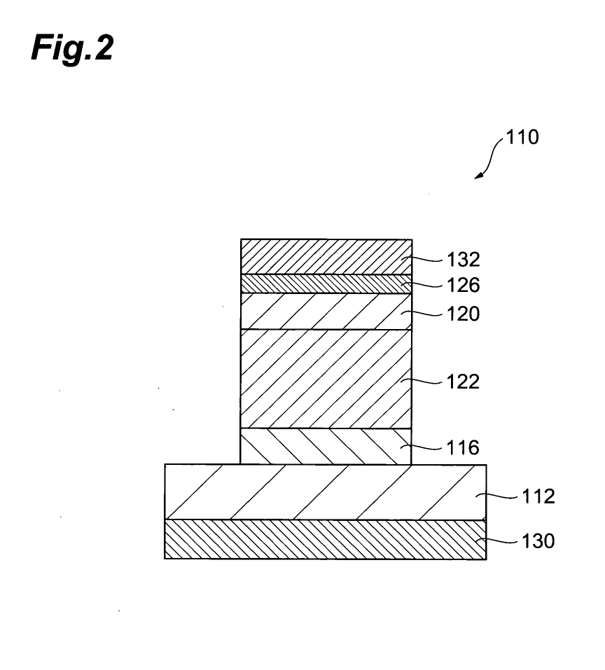

The following experiment was carried out to verify the increase in resistivity in GaInP on account of low-temperature growth. FIG. 2 illustrates the measurement samples used in the experiment. FIG. 2 is a cross-sectional diagram illustrating schematically a measurement sample for verifying resistivity increase in GaInP on account of low-temperature growth. The measurement sample 110 illustrated in FIG. 2 comprises a p-i-n structure in which an n-type GaAs substrate 112 has sequentially layered thereon an electron carrier supply layer 116, a high resistivity layer 122, a hole carrier supply layer 120, and a contact layer 126. Examples of the constitution of the various layers are given below. The various layers are grown, for instance, by organometallic vapor phase epitaxy.

Electron carrier supply layer 116: n-type GaInP, 0.5 μm thick, doped to 1×10¹⁷ cm⁻³ with silicon as an n-type dopant.
High resistivity layer 122: undoped GaInP, 1.5 μm thick
Hole carrier supply layer 120: p-type GaInP, 0.5 μm thick, doped to 7×10¹⁷ cm⁻³ with zinc as a p-type dopant
Contact layer 126: p-type GaAs, 0.2 μm thick, doped to 1×10¹⁹ cm⁻³ with zinc as a p-type dopant

The above carrier supply layers 116, 120 inject electrons and holes into the high resistivity layer 122. The growth temperature of undoped GaInP is preferably not lower than 500° C. The growth temperature of undoped GaInP is preferably not higher than 600° C. After growth, the p-i-n structure was processed into a circular mesa having a cross section diameter of 200 μm. For power supply, an anode electrode 132 was formed on the contact layer 126, while a cathode electrode 130 was formed on the reverse surface of the GaAs substrate 112. Forward bias was applied to the measurement sample 110, to measure the I-V characteristic and to calculate the resistivity (electric resistivity, measurement temperature: room temperature) based on the measurement values.

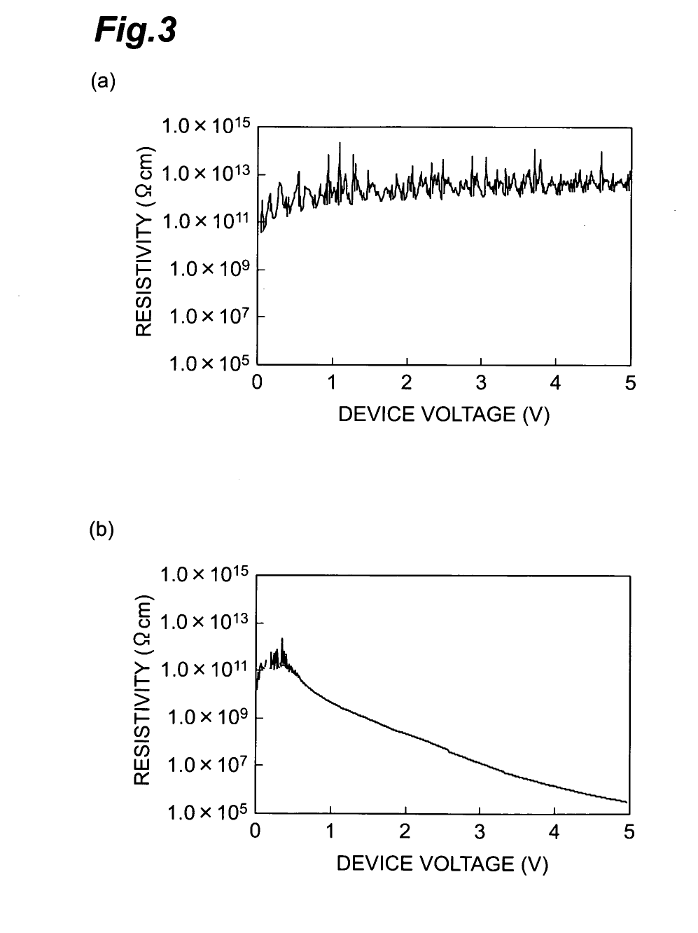

(a) of FIG. 3 is a graph illustrating the relationship between resistivity and applied voltage in a sample comprising undoped GaInP grown at 500° C. (b) of FIG. 3 is a graph illustrating the relationship between resistivity and applied voltage in a sample comprising undoped GaInP grown at 550° C. These results indicate that high resistivity, not lower than 10⁵ Ωcm, can be obtained within the range of forward biases that are ordinarily applied to semiconductor lasers (for instance, a voltage no higher than 5 V). The results indicate also that the lower the growth temperature is, the higher the resistivity becomes in the obtained GaInP. The characteristics in (a) of FIG. 3 and (b) of FIG. 3 indicate that low-temperature growth results in the formation, in the undoped GaInP layers, of a large number of trapping centers of electrons and holes. As a result, the layers sufficiently trap both electrons and holes, thereby exhibiting substantial resistivity to both carriers. The reason for that is when an undoped GaInP layer cannot trap either of the carriers, current of a non-negligible level flows on account of that carrier type, and in consequence the high resistivity characteristic illustrated in (a) of FIG. 3 and (b) of FIG. 3 cannot be obtained.

Based on the results of the experiments, we verified that an undoped GaInP layer grown at low temperature can exhibit a high resistivity, not lower than 10⁵ Ωcm, within the range of forward biases that are ordinarily applied to semiconductor lasers (for instance, a voltage no higher than 5 V), and that the undoped GaInP layer grown at low temperature functions as a high resistivity layer. By virtue of having such high resistivity, the undoped GaInP layer can be used as the burying layer 30. Device capacitance can be considerably reduced by using such a burying layer 30.

Dielectric layers comprising a dielectric material are known in conventional art as high-resistivity burying layers 30 in semiconductor optical devices such as the surface-emitting type semiconductor optical device 10.

However, using as a burying layer a dielectric layer comprising a dielectric material gives rise to excessive stresses in other semiconductor layers comprised in the semiconductor optical device, on account of the large difference between the coefficients of thermal expansion of the dielectric material and of semiconductors. Also, thermal resistance, which is large within the dielectric layer, impairs heat dissipation in the device. The characteristics and reliability of the device suffer thus on account of such excessive stresses and impaired heat dissipation. Moreover, owing to the large difference between the coefficients of thermal expansion of the dielectric layer and of the semiconductor layers, the use of a dielectric layer as a burying layer impairs adherence to adjacent semiconductor layers, which makes delamination likelier. The foregoing affords reduced manufacturing yields and lower productivity.

In the present embodiment, by contrast, an undoped GaInP semiconductor is used as the material of the burying layer 30, and hence the coefficient of thermal expansion of the burying layer 30 is substantially identical to that of the other semiconductor layers that make up the surface-emitting type semiconductor optical device 10. Therefore, there arise virtually no large differences in coefficient of thermal expansion vis-à-vis the above-described other semiconductor layers, as compared when, for instance, a dielectric layer is used as the burying layer. Similarly, higher heat dissipation can be realized in the burying layer 30 when the burying layer 30 comprises a semiconductor than when it comprises a dielectric material. Likewise, good adherence to adjacent semiconductor layers is achieved by using the burying layer 30 comprising a semiconductor layer, whose coefficient of thermal expansion is substantially identical to those of the adjacent other semiconductor layers.

This allows avoiding, as a result, the various above-described problems associated with using a dielectric layer as the burying layer, namely excessive stresses caused by differences in the coefficients of thermal expansion, and impairment of device characteristics and reliability on account of poorer heat dissipation. The loss of adherence caused by differences in the coefficient of thermal expansion, which occurs when using a dielectric layer, is now redressed, which allows avoiding, as a result, the above-described problem of lower manufacturing yields, and associated low productivity, derived from poor adherence.

Iron (Fe) doped semiconductors are also used as high-resistivity burying layers. That is, doping with Fe causes trapping centers to be formed in the semiconductor, which functions then as a high-resistivity layer to electrons. However, Fe-doped semiconductors have no hole trapping capability, and hence cannot function as a high-resistivity layer for p-type doped semiconductor layers, where hole carriers are predominant. It is difficult, therefore, to combine a Fe-doped semiconductor layer with a p-type doped semiconductor layer, which constrains thus flexibility in device design. If a Fe-doped semiconductor layer is combined with a p-type doped semiconductor layer, then a hole trapping layer must be additionally provided between the Fe-doped semiconductor layer and the p-type doped semiconductor layer, with a view to preventing intrusion of holes into the Fe-doped semiconductor layer. The additional hole trapping layer, however, increases device capacitance, which hinders achieving a high-speed device. The addition of a hole trapping layer, moreover, exacerbates growth load and process load, all of which impact on productivity. When using a semiconductor layer doped with an impurity such as Fe or the like as the burying layer, interdiffusion is ordinarily likely to occur between the impurities in the burying layer and the dopant impurities (for instance, Zn) in adjacent layers (mesa-shaped semiconductor layers, spacer layers and so forth). Parasitic capacitance increases then through the resulting lower resistivity of the Fe-doped semiconductor layer, into which impurities from adjacent layers have diffused, while, conversely, current flows less readily in the adjacent layers on account of the higher resistivity brought about by Fe diffusion. The foregoing impairs thus device characteristics and high speed.

By contrast, the undoped GaInP grown at low temperature that makes up the burying layer 30 has high resistivity to both electrons and holes, and can hence function as a high-resistivity burying layer in a semiconductor laser, both in p-type and n-type regions. This affords a greater flexibility in the design of current confinement structures, and facilitates structure optimization, as compared with the case when Fe-doped semiconductors are used. When using the undoped burying layer 30, as in the present embodiment, no special doping need be carried out using novel dopants such as Fe or the like, and hence growth is easier. The burden associated with growth can be alleviated, since there is no need for, for instance, preparing a dopant raw material, providing equipment for doping the dopant, and setting doping conditions. Productivity can thus be increased as a result. The burying layer 30, moreover, is undoped, and hence there occurs no interdiffusion between impurities in the burying layer and impurities in adjacent layers during growth, as is the case when using a high-resistivity burying layer doped with impurities. Accordingly, characteristics and high speed do not become impaired, which is a serious problem when using a semiconductor burying layer having had the resistivity thereof increased through doping with impurities, on account of a lowering of the resistivity of the burying layer and an increase in the resistivity of adjacent layers brought about by interdiffusion.

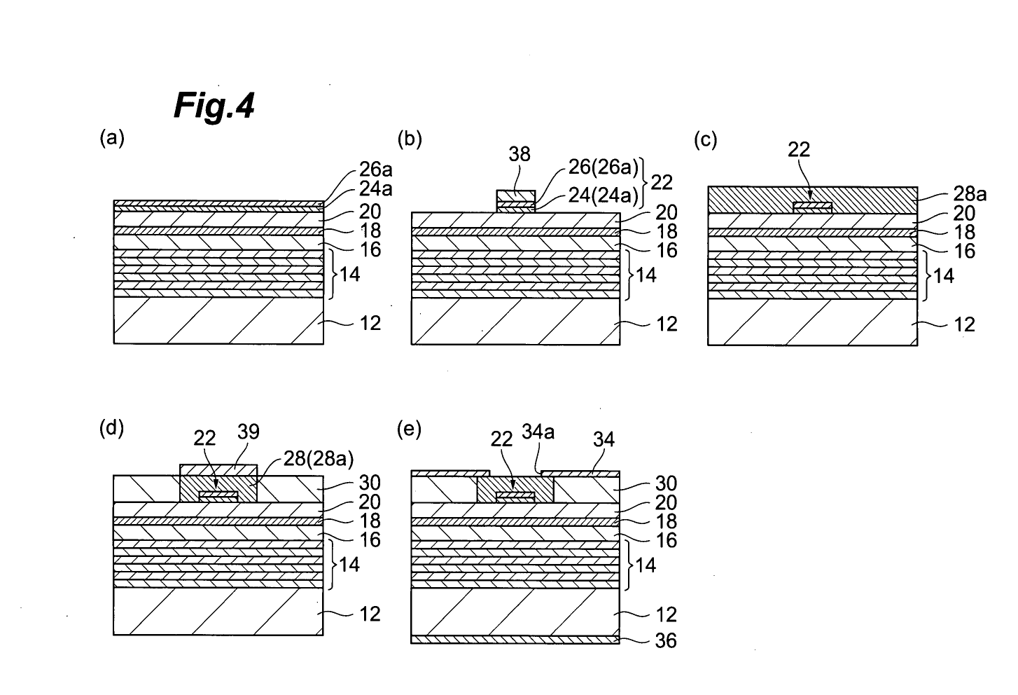

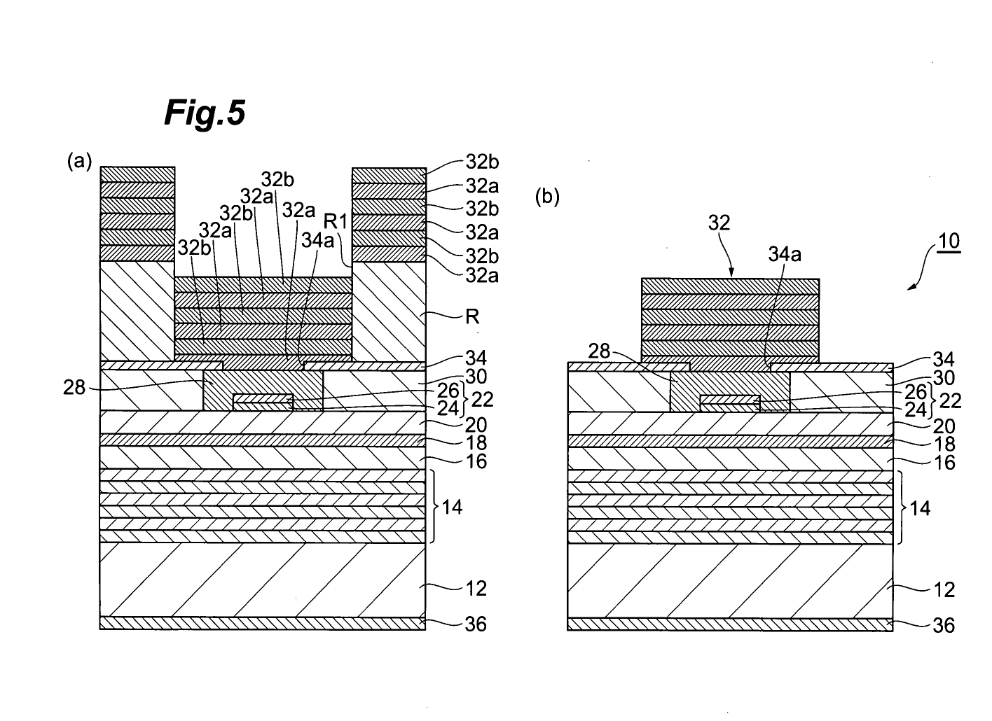

An example of a method for manufacturing the surface-emitting type semiconductor optical device 10 is explained next. (a) of FIG. 4 to (e) of FIG. 4, (a) of FIG. 5 and (b) of FIG. 5 are cross-sectional diagrams of the steps of a method for manufacturing a surface-emitting type semiconductor optical device according to the first embodiment. Unless otherwise specified, all the semiconductor layers are grown by organometallic vapor phase epitaxy (OMVPE).

As illustrated in (a) of FIG. 4, the first DBR portion 14, the spacer layer 16 and the active layer 18 are sequentially grown first on the GaAs substrate 12. In an example where the active layer 18 comprises GaInNAs, the active layer 18 is grown by OMPVE at a growth temperature of 500 to 550° C. using, for instance, TEG (triethyl gallium), TMI (trimethyl indium), DMHy (dimethyl hydrazine) and TBA (tertiary butylarsine) as raw materials. Once the active layer 18 is grown, there are sequentially grown the spacer layer 20, the semiconductor layer (second layer) 24a for forming the semiconductor layer 24 and the semiconductor layer (third layer) 26a for forming the semiconductor layer 26.

Next, as illustrated in (b) of FIG. 4, a resist mask 38 having a predetermined pattern is formed on the semiconductor layer 26a, whereafter the semiconductor layers 24a, 26a are etched to form the mesa-shaped tunnel junction 22. Various different mesa shapes, such as reverse mesa, normal mesa or the like, can be selected for the tunnel junction 22, in accordance with the intended application, by appropriately selecting, for instance, the plane orientation for mask formation, the etchant and so forth.

The pattern formation of the resist mask 38 may be appropriately selected from among, for instance, a circular or square shape, in such a manner that the tunnel junction 22 takes on a desired shape as a current confinement portion.

Examples of etching include, for instance, wet etching. When, for instance, GaInP or AlGaInP is used in the spacer layer 20 and GaInAs is used in the semiconductor layers 24a, 26a, and a phosphoric acid-based etchant is used for etching the semiconductor layers 24a, 26a, then the etching rate of the spacer layer 20 is lower than the etching rate of the semiconductor layers 24a, 26a, and hence the spacer layer 20 functions as an etching stop layer. Therefore, the mesa shape (mesa height and mesa width) of the tunnel junction 22 can be controlled with good reproducibility and in-plane uniform even when the etching rate of the semiconductor layers 24a, 26a varies across the wafer or for each manufacturing run (lot). This allows ensuring as a result reproducibility and uniformity of laser characteristics. However, the spacer layer 20 need not necessarily be an etching stop layer. Etching that yields good reproducibility and uniformity can be achieved by optimizing the etching process and etching conditions, even without the spacer layer 20 functioning as an etching stop layer.

As illustrated in (c) of FIG. 4, the resist mask 38 is removed next, whereafter a semiconductor layer (first layer) 28a that is the conductive layer 28 is grown on the spacer layer 20. Next, as illustrated in (d) of FIG. 4, a dielectric mask 39 is formed on a predetermined region above the tunnel junction 22, on the surface of the semiconductor layer 28a. Thereafter, the semiconductor layer 28a is etched to form thereby the mesa-shaped conductive layer 28. The dielectric mask 39 comprises for instance SiN, SiO₂ or the like. To bury next the conductive layer 28, the burying layer 30, comprising undoped GaInP, is regrown on the spacer layer 20, to a thickness identical to the thickness of the conductive layer 28. The burying layer 30 is grown at low temperature, as described above.

When the burying layer 30 comprises undoped GaInP, the growth temperature of the burying layer 30 is preferably not higher than 600° C., more preferably of 500° C. to 550° C. Growing thus the burying layer 30 at a low temperature allows preventing deterioration of the active layer 18 on account of excessive thermal stress during growth of the burying layer 30. The burying layer 30, which can be grown at the above low temperatures, is ideally used when, for instance, III-V compound semiconductor mixed crystals, comprising Ga, As and N such as GaInNAs, which are sensitive to thermal stress, are used in the active layer 18.

Next, as illustrated in (e) of FIG. 4, an electrode 34 for power supply is formed on the conductive layer 28 and the burying layer 30. The electrode 34 is formed to a shape having an opening 34a at a region that allows the light from the active layer 18 to be transmitted without being blocked, i.e. a region above the tunnel junction 22. An electrode 36 for power supply is likewise formed on the reverse face of the substrate 12.

A method for forming the second DBR portion 32 is explained next, in an example where the second DBR portion 32 comprises, for instance, a dielectric multilayer film of TiO₂/SiO₂, a-Si/SiO₂, and so on. As illustrated in (a) of FIG. 5 and (b) of FIG. 5, the second DBR portion 32 is formed on the conductive layer 28, for instance, by lift off. Specifically, a resist film R is formed on a predetermined region of the electrode 34, as illustrated in (a) of FIG. 5. The resist film R is formed so as to have an opening R1 over the opening 34a of the electrode 34. The DBR layers 32a, 32b that make up the second DBR portion 32 are alternately layered next. To that end, the DBR layers 32a and the DBR layers 32b may be alternately deposited in such a way so as to bury the opening 34a of the electrode 34 and the opening R1 of the resist film R.

As illustrated in (b) of FIG. 5, the DBR layers 32a, 32b positioned on the resist film R are removed by removing the resist film R. The second DBR portion 32 is selectively formed thereby on the tunnel junction 22, thus completing the VCSEL structure, and yielding the surface-emitting type semiconductor optical device 10. In the above manufacturing method, the second DBR portion 32 is formed in such a manner that part thereof is positioned on the electrode 34, as illustrated in FIG. 1 and (b) of FIG. 5.

As explained above, undoped GaInP, which is a semiconductor, is used as the material of the burying layer 30 in the surface-emitting type semiconductor optical device 10. As a result, there arise virtually no differences vis-à-vis the coefficients of thermal expansion of the other semiconductor layers comprised in the surface-emitting type semiconductor optical device 10. This reduces damage caused by stresses exerted on the other semiconductor layers. Likewise, using a semiconductor in the burying layer 30 allows realizing higher heat dissipation ability than is the case when the burying layer 30 comprises a dielectric material. Good device characteristics and reliability can be realized as a result. Since the burying layer 30 comprises a semiconductor, there arise virtually no differences vis-à-vis the coefficients of thermal expansion of adjacent other semiconductor layers, which affords thus good adherence to these adjacent other semiconductor layers. Productivity of the surface-emitting type semiconductor optical device 10 is improved as a result.

The low-temperature grown undoped GaInP that makes up the burying layer 30 has high resistivity to both electrons and holes, and can hence function as a burying layer in a semiconductor laser, both in p-type and n-type regions. This affords a greater flexibility in the design of buried structures, and facilitates structure optimization. Also, the GaInP in the burying layer 30 is undoped, and hence no interdiffusion occurs between the burying layer 30 and adjacent layers, and hence no characteristics such as high speed or the like become impaired on account of interdiffusion. Since the surface-emitting type semiconductor optical device 10 uses an undoped burying layer 30, there is no need for specially doping a novel dopant, which makes growth easier. For instance, there is no need for preparing a dopant raw material, providing equipment for doping the dopant, and setting doping conditions. This can alleviate as a result the burden associated with forming the burying layer 30, so that productivity of the surface-emitting type semiconductor optical device 10 is improved as a result.

When the second DBR portion 32 comprises a semiconductor multilayer film, a high-resistivity burying layer can conceivably be formed in the second DBR portion. In that case, the high-resistivity semiconductor burying layer is formed as follows.

Firstly, growth of the second DBR portion is discontinued halfway. Next, the outer periphery of the second DBR portion is removed by etching, to form a mesa-shaped second DBR portion. Then a semiconductor burying layer is regrown around the second DBR portion, in such a way so as to bury the latter. Thereafter, the remaining second DBR portion is regrown.

However, when growth of the second DBR portion is discontinued halfway, unexpected structures such as a native oxide film are likelier to form on the surface of the second DBR portion, and hence controlling the reflectivity of the second DBR portion as designed tends to be more difficult. As a result, it is difficult to raise the reflectivity of the second DBR portion to the high reflectivity, not lower than 99%, that VCSEL oscillation requires. During etching of the second DBR portion, moreover, defects such as non-radiative centers are likely to occur on the surface of the mesa-shaped second DBR portion formed by etching. Such defects deteriorate the second DBR portion and constitute one factor that impairs device reliability. In particular, the second DBR portion comprises ordinarily a semiconductor material having a high Al composition ratio, and hence oxidizes readily, which makes such non-radiative centers likelier to occur on the etched surface.

In the present embodiment, on the other hand, the second DBR portion 32 is separated from the burying layer 30. Accordingly, the second DBR portion 32 can be grown without discontinuing growth, even when the second DBR portion 32 comprises a semiconductor multilayer film, and thus the above-described degradation of the second DBR portion 32 is forestalled. As a result, controllability of the reflectivity of the second DBR portion 32, as well as device reliability, are not impaired, as compared with the case when the second DBR portion is buried in a burying layer.

### Second Embodiment

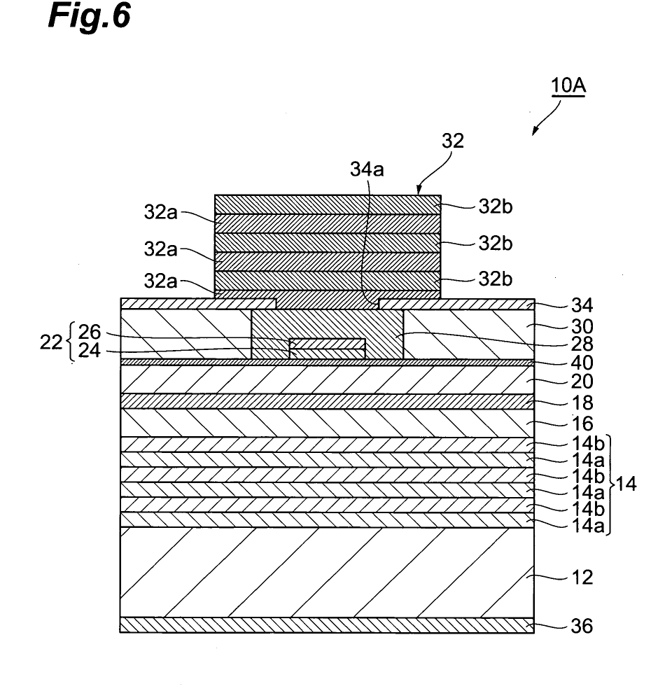

FIG. 6 is a cross-sectional diagram illustrating schematically a surface-emitting type semiconductor optical device according to a second embodiment. In addition to the constitution of the surface-emitting type semiconductor optical device 10, the surface-emitting type semiconductor optical device 10A illustrated in FIG. 6 further comprises an interlayer (first interlayer) 40 of second conductivity type (in the present embodiment, for instance, p-type) provided between the tunnel junction 22 and the spacer layer 20. The interlayer 40 can comprise, for instance, AlGaInP or GaInP.

An example of a method for manufacturing the surface-emitting type semiconductor optical device 10A is explained next.

As in the process illustrated in (a) of FIG. 4, the first DBR portion 14, the spacer layer 16, the active layer 18, the spacer layer 20, the interlayer 40, the semiconductor layer 24a and the semiconductor layer 26a are sequentially grown first on the GaAs substrate 12.

Next, as in the process illustrated in (b) of FIG. 4, the mesa-shaped tunnel junction 22 is formed by etching the semiconductor layers 24a, 26a using the resist mask 38.

For instance, a phosphoric acid-based etchant is preferably used as the etchant when the spacer layer 20 comprises any among GaAs, AlGaAs and GaInAsP, the semiconductor layers 24a, 26a comprise GaInAs, and the interlayer 40 comprises AlGaInP or GaInP. In this case, the etching rate of the interlayer 40 is lower than the etching rate of the semiconductor layers 24a, 26a, and hence the interlayer 40 functions as an etching stop layer. Therefore, the mesa shape (mesa height and mesa width) of the tunnel junction 22 can be controlled with good reproducibility and in-plane uniformity even when the etching rate of the semiconductor layers 24a, 26a varies across the wafer or for each manufacturing run (lot). This allows ensuring in turn good reproducibility and good uniformity in the laser characteristics of the surface-emitting type semiconductor optical device 10A.

Thereafter the surface-emitting type semiconductor optical device 10A is obtained through a process comprising the same steps as illustrated in (c) of FIG. 4 to (e) of FIG. 4, (a) of FIG. 5 and (b) of FIG. 5.

Except for the presence of the interlayer 40, the constitution of the surface-emitting type semiconductor optical device 10A is identical to that of the surface-emitting type semiconductor optical device 10. Therefore, the surface-emitting type semiconductor optical device 10A elicits the same effect as the surface-emitting type semiconductor optical device 10. In the surface-emitting type semiconductor optical device 10A, moreover, the interlayer 40 functions as an etching stop layer during formation of the tunnel junction 22, as described above. Therefore, the mesa shape of the tunnel junction 22 can be controlled with good reproducibility and in-plane uniformity. The surface-emitting type semiconductor optical device 10A as well can exhibit good uniformity and reproducibility with its characteristics. Using the interlayer 40 is particularly preferred when the spacer layer 20 does not function as an etching stop layer.

AlGaInP or GaInP has been cited as the material of the interlayer 40. However, the material that makes up the interlayer 40 may comprise a material that grows appropriately on the spacer layer 20 and that can be used as the etching stop layer during formation of the tunnel junction 22 comprising the semiconductor layers 24, 26.

### Third Embodiment

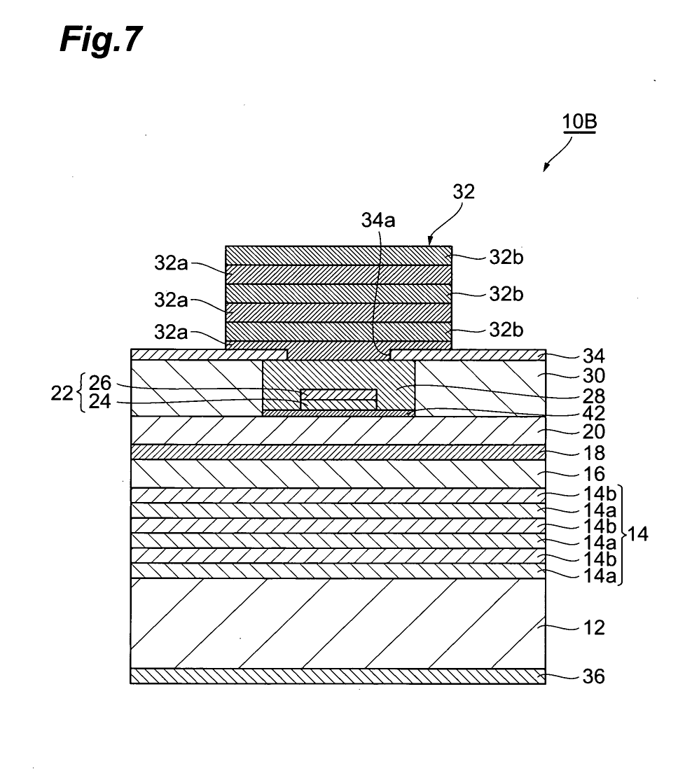

FIG. 7 is a cross-sectional diagram illustrating schematically a surface-emitting type semiconductor optical device according to a third embodiment. In addition to the constitution of the surface-emitting type semiconductor optical device 10, the surface-emitting type semiconductor optical device 10B illustrated in FIG. 7 further comprises an interlayer (first interlayer) 42 of second conductivity type provided only between the conductive layer 28, in which the tunnel junction 22 is embedded, and the spacer layer 20. The interlayer 42 comprises for instance the same material as the interlayer 40. In the present embodiment the interlayer 42 is not provided between the burying layer 30 and the spacer layer 20.

An example of a method for manufacturing the surface-emitting type semiconductor optical device 10B is explained next.

Firstly the tunnel junction 22 is formed (see (a) of FIG. 4 and (b) of FIG. 4), in the same way as in the method for manufacturing the surface-emitting type semiconductor optical device 10A. In the present embodiment the tunnel junction 22 is formed on the interlayer 40.

The conductive layer 28a is grown next as in the step (c) of FIG. 4. In the present embodiment, the conductive layer 28a is grown on the interlayer 40. Thereafter, as explained for the step of (d) of FIG. 4, the dielectric mask 39 is formed on a predetermined region of the surface of the conductive layer 28a, and then the mesa-shaped conductive layer 28 is formed through etching of the conductive layer 28a.

The interlayer 42 is formed next through etching of the interlayer 40. For instance, a phosphoric acid-based etchant is used as the etchant for etching the conductive layer 28a when the spacer layer 20 comprises any among GaAs, AlGaAs and GaInAsP, the conductive layer 28a comprises GaAs, and the interlayer 40 comprises AlGaInP or GaInP. Thereby, the interlayer 40 comprising AlGaInP or GaInP functions as an etching stop layer. For instance, a hydrochloric acid-based etchant is used as the etchant for forming the interlayer 42 through etching of the interlayer 40. Thereby, the spacer layer 20, comprising any among GaAs, AlGaAs and GaInAsP, functions as an etching stop layer.

Through appropriate selection of the etchant, the interlayer 40 and the spacer layer 20 function as respective etching stop layers. Therefore, the mesa comprising the conductive layer 28 and the interlayer 42 can be fabricated with good reproducibility and in-plane uniformity.

After formation of the interlayer 42, the burying layer 30 is regrown on the spacer layer 20, as is the case in the explanation of (d) of FIG. 4 in the first embodiment.

Thereafter the surface-emitting type semiconductor optical device 10B is obtained through a process comprising the same steps as illustrated in (e) of FIG. 4, (a) of FIG. 5 and (b) of FIG. 5.

The surface-emitting type semiconductor optical device 10B affords the same effect as the surface-emitting type semiconductor optical devices in the embodiments above. Herein, the interlayer 42 is formed only between the conductive layer 28 and the spacer layer 20, and hence the characteristics of the surface-emitting type semiconductor optical device 10B can be improved by controlling the characteristics of the interlayer 42. For instance, the material of the interlayer 42 is selected to have a higher refractive index than that of the material of the burying layer 30. In this case, light is strongly confined in the light-emitting region, which as a result allows improving the oscillation characteristics of the surface-emitting type semiconductor optical device 10B.

### Fourth Embodiment

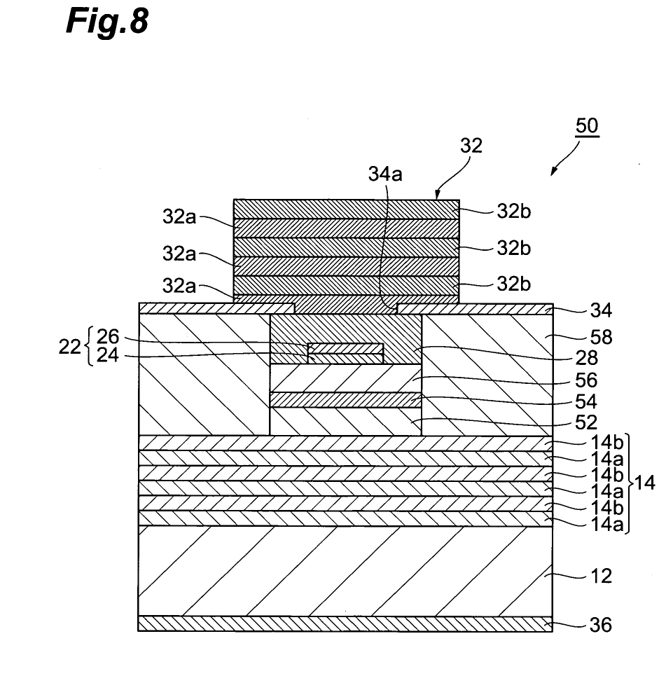

FIG. 8 is a cross-sectional diagram illustrating schematically a surface-emitting type semiconductor optical device according to a fourth embodiment. The surface-emitting type semiconductor optical device 50 illustrated in FIG. 8 comprises a mesa-shaped spacer layer 52, a mesa-shaped active layer 54, a mesa-shaped spacer layer 56 and a burying layer 58 in lieu of the spacer layer 16, the active layer 18, the spacer layer 20 and the burying layer 30 of the surface-emitting type semiconductor optical device 10. The spacer layer 52, the active layer 54, the spacer layer 56 and the burying layer 58 comprise the same materials as the spacer layer 16, the active layer 18, the spacer layer 20 and the burying layer 30, respectively. The burying layer 58 is provided on the side faces of the spacer layer 52, the side faces of the active layer 54, the side faces of the spacer layer 56 and the side faces of the conductive layer 28.

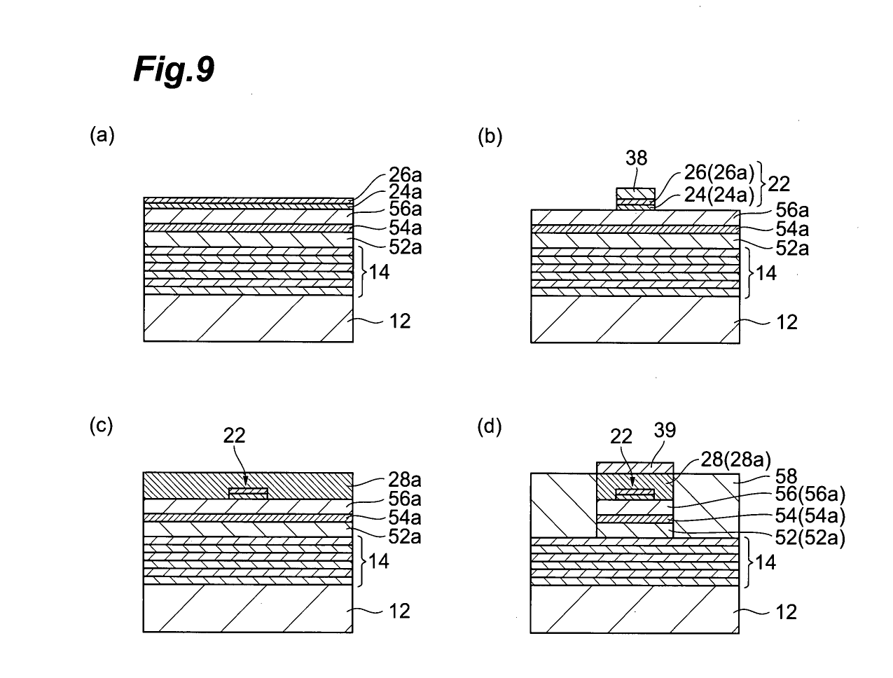

An example of a method for manufacturing the surface-emitting type semiconductor optical device 50 is explained next. (a) of FIG. 9 to (d) of FIG. 9 are cross-sectional diagrams of the steps of a method for manufacturing the surface-emitting type semiconductor optical device according to the fourth embodiment.

As illustrated in (a) of FIG. 9, there are firstly sequentially formed, on the GaAs substrate 12, the first DBR portion 14, a spacer layer 52a for forming the spacer layer 52, an active layer 54a for forming the active layer 54, a spacer layer 56a for forming the spacer layer 56, a semiconductor layer 24a and a semiconductor layer 26a.

Next, as illustrated in (b) of FIG. 9, a resist mask 38 having a predetermined pattern is formed on the semiconductor layer 26a, whereafter the semiconductor layers 24a, 26a are etched to form the mesa-shaped tunnel junction 22, in the same way as in (b) of FIG. 4. As illustrated in (c) of FIG. 9, the resist mask 38 is removed next, whereafter the conductive layer 28a for forming the conductive layer 28 is grown on the spacer layer 56a.

Next, as illustrated in (d) of FIG. 9, a dielectric mask 39 is formed on a predetermined region of the surface of the conductive layer 28a, above the tunnel junction 22, whereafter the conductive layer 28a, the spacer layer 56a, the active layer 54a and the spacer layer 52a are removed through etching. The spacer layer 52, the active layer 54, the spacer layer 56 and the conductive layer 28 are formed as a result. The burying layer 58 is regrown thereafter on the first DBR portion 14, to bury thereby the spacer layer 52, the active layer 54, the spacer layer 56 and the conductive layer 28. The burying layer 58 is grown at low temperature, as is the case in (d) of FIG. 4.

Etching in the etching step for forming the spacer layers 52, 56, the active layer 54 and the conductive layer 28 may be, for instance, wet etching. Herein, for instance, the spacer layers 52a, 56a may comprise any among AlGaAs, GaAs and GaInAsP, the active layer 54a may comprise GaInNAs quantum wells and a GaAs barrier layer, the conductive layer 28a may comprise GaAs, and the first DBR portion 14 may comprise a multilayer film in which either AlAs or AlGaAs is alternately layered with GaAs.

In that case, the spacer layers 52a, 56a, the active layer 54a and the conductive layer 28a can be etched collectively using, for instance, a phosphoric acid-based etchant, to form thereby the spacer layer 52, the active layer 54, the spacer layer 56 and the conductive layer 28. The uppermost layer of the first DBR portion 14 that is in contact with the spacer layer 52 is preferably a GaAs layer, and not an AlAs layer or an AlGaAs layer that comprises a substantial amount of readily-oxidizable Al. The reason for this is that when the uppermost layer comprises AlAs layer or an AlGaAs layer, the uppermost layer comprising a substantial amount of Al becomes exposed after etching of the spacer layer 52a. The uppermost layer oxidizes readily as a result, giving rise to numerous defects, impairing crystallinity, and hampering thus regrowth of the burying layer 58 on the oxidized surface.

When, for instance, the spacer layers 52a, 56a comprise GaInP or AlGaInP, the active layer 54a comprises GaInNAs/GaAs, the conductive layer 28a comprises GaAs, and the first DBR portion 14 comprises a semiconductor multilayer film that comprises GaAs and either AlGaAs or AlAs (the uppermost layer is a GaAs layer), then a phosphoric acid-based etchant is preferably used for etching the conductive layer 28a and the active layer 54a, and a hydrochloric acid-based etchant is used for etching the spacer layers 52a, 56a.

In this case, the etching rate of the spacer layers 52a, 56a by the phosphoric acid-based etchant is lower than the etching rate of the conductive layer 28a and the active layer 54a by the phosphoric acid-based etchant, and hence the spacer layer 56a and the spacer layer 52a function as etching stop layers during etching of the conductive layer 28a and the active layer 54a. On the other hand, the etching rate of the active layer 54a and the uppermost layer (GaAs) of the first DBR portion 14 by the hydrochloric acid-based etchant is lower than the etching rate of the spacer layers 52a, 56a by the hydrochloric acid-based etchant, and hence the active layer 54a and the uppermost layer (GaAs) of the first DBR portion 14 function as etching stop layers during etching of the spacer layer 56a and the spacer layer 52a. A mesa comprising the conductive layer 28, the spacer layer 56, the active layer 54 and the spacer layer 52 is obtained as a result that has a shape with good reproducibility and in-plane uniformity. This allows ensuring in turn good reproducibility and uniformity with the characteristics of the surface-emitting type semiconductor optical device 50.

From the step of (d) of FIG. 9 onward, the surface-emitting type semiconductor optical device 50 illustrated in FIG. 8 is obtained through a process comprising the same steps as illustrated in (e) of FIG. 4, (a) of FIG. 5 and (b) of FIG. 5.

The surface-emitting type semiconductor optical device 50 affords the same effect as the surface-emitting type semiconductor optical device 10 according to the first embodiment. Moreover, the burying layer 58 can be made thicker than the burying layer of, for instance, the surface-emitting type semiconductor optical device 10, thereby reducing device capacitance and enabling a faster operation. In the surface-emitting type semiconductor optical device 10, the spacer layers and the active layer extend across the entire device, so that no refractive index differences in the horizontal direction occur within those regions. In the present embodiment, on the other hand, the burying layer 58 is provided on the side faces of the spacer layers 52, 56 and the active layer 54. The refractive index of the burying layer 58, comprising GaInP, is ordinarily lower than the refractive index of the active layer 54. Thanks to this refractive index difference, the light-emitting region in the device center, where the tunnel junction 22 is present, exhibits a higher effective refractive index than the surrounding region, where the burying layer 58 is present. This allows light to be strongly confined in the active layer 54. As a result, stimulated emission takes place then with good efficiency. The oscillation characteristics of the VCSEL become further enhanced thereby.

### Fifth Embodiment

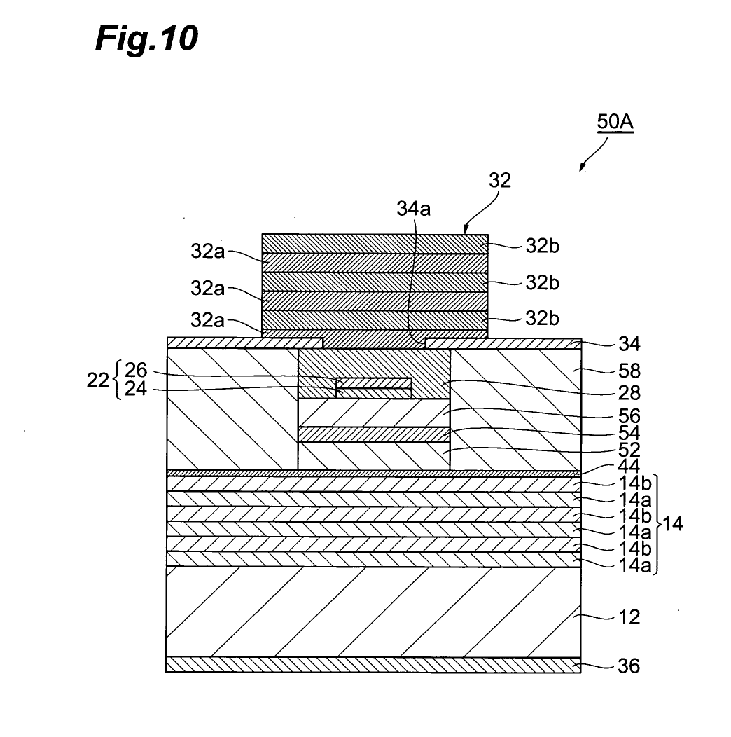

FIG. 10 is a cross-sectional diagram illustrating schematically a surface-emitting type semiconductor optical device according to a fifth embodiment. In addition to the constitution of the surface-emitting type semiconductor optical device 50, the surface-emitting type semiconductor optical device 50A illustrated in FIG. 10 further comprises an interlayer (second interlayer) 44 of first conductivity type provided between first DBR portion 14 and the spacer layer 52 and the burying layer 58. The interlayer 44 can comprise, for instance, any one among GaInP, AlGaInP, GaAs, AlGaAs and GaInAsP.

An example of a method for manufacturing the surface-emitting type semiconductor optical device 50A is explained next.

As in the step illustrated in (a) of FIG. 9, the first DBR portion 14, the interlayer 44, the spacer layer 52a, the active layer 54a, the spacer layer 56a, and the semiconductor layers 24a and 26a are sequentially grown first on the GaAs substrate 12. The conductive layer 28a, in which the tunnel junction 22 is embedded, is formed next as in the process illustrated in (b) of FIG. 9 and (c) of FIG. 9.

The conductive layer 28a, the spacer layer 56a, the active layer 54a and the spacer layer 52a are etched next using a dielectric mask 39, as in the step illustrated in (d) of FIG. 9. The conductive layer 28, the spacer layer 56, the active layer 54 and the spacer layer 52 are formed as a result.

When, for instance, the spacer layers 52a, 56a comprise GaAs, AlGaAs or GaInAsP, the active layer 54a comprises GaInNAs/GaAs, the conductive layer 28a comprises GaAs, and the interlayer 44 comprises GaInP or AlGaInP, then the etchant used in the etching step for forming the spacer layers 52, 56, the active layer 54 and the conductive layer 28 is preferably a phosphoric acid-based etchant.

Herein, a phosphoric acid-based etchant allows etching simultaneously the spacer layer 52a, 56a, the active layer 54a and the conductive layer 28a. When the interlayer 44 comprises GaInP or AlGaInP, the etching rate of the interlayer 44 by the phosphoric acid-based etchant is low, and hence the interlayer 44 functions as an etching stop layer during etching of the spacer layer 52a. A mesa comprising the conductive layer 28, the spacer layer 56, the active layer 54 and the spacer layer 52 is obtained as a result having good reproducibility and in-plane uniformity. This allows ensuring in turn good reproducibility and uniformity with the characteristics of the surface-emitting type semiconductor optical device 50A.

When, for instance, the spacer layers 52a, 56a comprise GaInP or AlGaInP, the active layer 54a comprises GaInNAs/GaAs, the conductive layer 28a comprises GaAs, and the interlayer 44 comprises GaAs, AlGaAs or GaInAsP, then a phosphoric acid-based etchant can be used for etching the conductive layer 28a and the active layer 54a, and a hydrochloric acid-based etchant can be used for etching the spacer layers 52a, 56a.

In this case, the etching rate of the spacer layers 52a, 56a by the phosphoric acid-based etchant is lower than the etching rate of the conductive layer 28a and the active layer 54a by the phosphoric acid-based etchant, and hence the spacer layer 56a and the spacer layer 52a function as etching stop layers during etching of the conductive layer 28a and the active layer 54a. On the other hand, the etching rate of the active layer 54a and the interlayer 44 by the hydrochloric acid-based etchant is lower than the etching rate of the spacer layers 56a, 52a by the hydrochloric acid-based etchant, and hence the active layer 54a and the interlayer 44 function as etching stop layers during etching of the spacer layer 56a and the spacer layer 52a. A mesa comprising the conductive layer 28, the spacer layer 56, the active layer 54 and the spacer layer 52 is obtained as a result having good reproducibility and in-plane uniformity. The surface-emitting type semiconductor optical device 50A as well can exhibit thereby good uniformity and reproducibility with its characteristics.

Thereafter the surface-emitting type semiconductor optical device 50A is obtained through a process comprising the same steps as illustrated in (e) of FIG. 4, (a) of FIG. 5 and (b) of FIG. 5.

Except for further comprising the interlayer 44, the constitution of the surface-emitting type semiconductor optical device 50A is identical to that of the surface-emitting type semiconductor optical device 50. Therefore, the surface-emitting type semiconductor optical device 50A elicits the same effect as the surface-emitting type semiconductor optical device 50 according to the fourth embodiment. In the surface-emitting type semiconductor optical device 50A, the interlayer 44 functions as an etching stop layer during etching of the spacer layer 52. A mesa comprising the conductive layer 28, the spacer layer 56, the active layer 54 and the spacer layer 52 is obtained as a result having good reproducibility and in-plane uniformity. This allows ensuring in turn good reproducibility and uniformity with the characteristics of the surface-emitting type semiconductor optical device 50A. The interlayer 44 is preferably used, in particular, when the first DBR portion 14 does not function as an etching stop layer.

### Sixth Embodiment

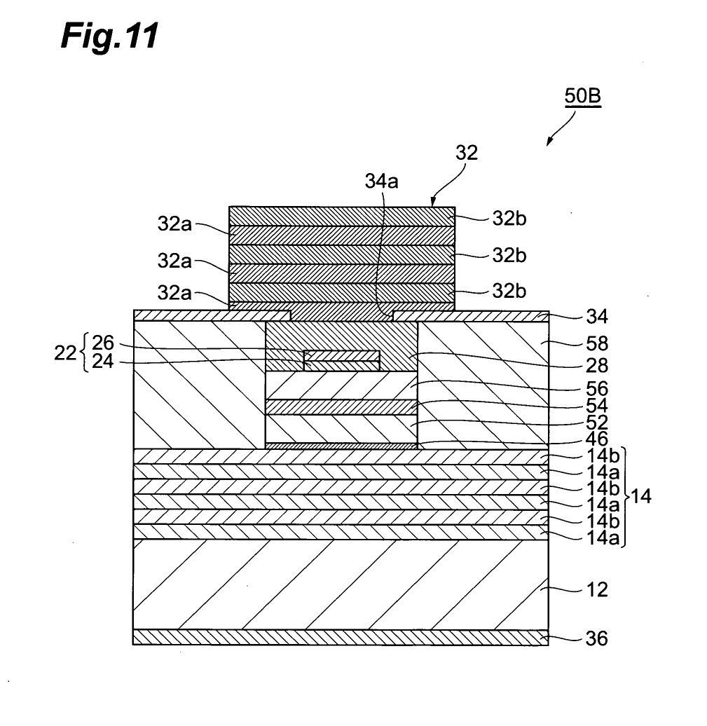

FIG. 11 is a cross-sectional diagram illustrating schematically a surface-emitting type semiconductor optical device according to a sixth embodiment. In addition to the constitution of the surface-emitting type semiconductor optical device 50, the surface-emitting type semiconductor optical device 50B illustrated in FIG. 11 further comprises an interlayer 46 of first conductivity type provided only between the first DBR portion 14 and the spacer layer 52. The interlayer 46 may comprise for instance the same material as the interlayer 44.

An example of a method for manufacturing the surface-emitting type semiconductor optical device 50B is explained next.

Firstly, the first DBR portion 14, the interlayer 44, the spacer layer 52a, the active layer 54a, the spacer layer 56a and the semiconductor layers 24a, 26a are sequentially grown on the GaAs substrate 12, in the same way as in the step illustrated in (a) of FIG. 9, using the same method for manufacturing the surface-emitting type semiconductor optical device 50A. The process is carried out next up to the steps illustrated in (b) of FIG. 9 and (c) of FIG. 9, to form the conductive layer 28a in which the tunnel junction 22 is embedded. Next, as illustrated in (d) of FIG. 9, a dielectric mask 39 is formed on a predetermined region of the surface of the conductive layer 28a, whereafter the conductive layer 28a, the spacer layers 52a, 56a, and the active layer 54a are removed through etching to form a mesa. The etching step may be identical to that of the surface-emitting type semiconductor optical device 50A.

In the manufacture of the surface-emitting type semiconductor optical device 50B, the interlayer 44 is etched next using the dielectric mask 39, to form a mesa-shaped interlayer 46.

When, for instance, the interlayer 44 comprises GaInP or AlGaInP, and the first DBR portion 14 comprises a multilayer film of GaAs and AlAs or AlGaAs, then the uppermost layer of the semiconductor multilayer film that constitutes the first DBR portion 14 comprises preferably, for instance, GaAs, while, for instance, a hydrochloric acid-based etchant is preferably used as the etchant for etching the interlayer 44. Herein, the etching rate of the uppermost layer (GaAs) of the first DBR portion 14 by the hydrochloric acid-based etchant is lower than the etching rate of the interlayer 44 by the hydrochloric acid-based etchant, and hence the uppermost layer (GaAs) of the first DBR portion 14 function as an etching stop layer. A mesa comprising the conductive layer 28, the spacer layer 56, the active layer 54, the spacer layer 52 and the interlayer 46 is obtained as a result having good reproducibility and in-plane uniformity. The surface-emitting type semiconductor optical device 50B as well can exhibit thereby good uniformity and reproducibility with its characteristics.

Thereafter, the surface-emitting type semiconductor optical device 50B is obtained through a process comprising the same steps as illustrated in (e) of FIG. 4, (a) of FIG. 5 and (b) of FIG. 5.

The constitution of the surface-emitting type semiconductor optical device 50A in the present embodiment differs from that of the surface-emitting type semiconductor optical device 50A in that in the present embodiment the interlayer 46 is not provided between the burying layer 58 and the first DBR portion 14, all other features being identical. The surface-emitting type semiconductor optical device 50B affords thus the same effect as the surface-emitting type semiconductor optical devices in the fourth and fifth embodiments. In the present embodiment, moreover, the interlayer 46 is provided only between the first DBR portion 14 and the spacer layer 52, and hence the characteristics of the surface-emitting type semiconductor optical device 50B can be improved by controlling the characteristics of the interlayer 46, as is the case in the surface-emitting type semiconductor optical device 10B. For instance, using in the interlayer 46 a material having a higher refractive index than that of the burying layer 58 allows light to be more strongly confined in the light-emitting region, and allows thus achieving yet better oscillation characteristics.

Embodiments of the present invention have been thus explained. The present invention, however, is not limited to VCSELs. Besides VCSELs, the above embodiments can also be applied to optical modulators, optical amplifiers, optical switches or the like having a vertical cavity structure.

When a semiconductor multilayer film is used in the second DBR portion 32, in the first to sixth embodiments, the semiconductor multilayer film may be doped to a first conductivity type, and the electrode 34 may be formed on the second DBR portion 32. In this case the second DBR portion 32 is of a first conductivity type, and hence current can be injected via the second DBR portion 32. Herein, however, the electrode 34 must be processed into a shape that does not hamper extraction of light from the second DBR portion 32.

The conductive layer (first semiconductor layer) 28 and the burying layer 30 are provided between the active layer 18 and the second DBR portion 32, but may also be provided between the active layer 18 and the first DBR portion 14.

In the fourth to sixth embodiments, the interlayers 40, 42 of second conductivity type are provided, as etching stop layers, between the tunnel junction 22 and the spacer layer 56, as explained in the second and third embodiments.

Thus far, the current confinement portion 22 has been explained as the tunnel junction 22 in which there are layered a second semiconductor layer 24 and a third semiconductor layer 26 having mutually different conductivity types. The current confinement portion 22, however, is not limited thereto, and can have, for instance, a current confinement structure such as a structure using a selectively oxidized semiconductor layer, a proton-implanted structure or the like.

From the invention thus described, it will be obvious that the invention may be varied in many ways. Such variations are not to be regarded as a departure from the spirit and scope of the invention, and all such modifications as would be obvious to one skilled in the art are intended for inclusion within the scope of the following claims.

What is claimed is:

1. A method for manufacturing a surface-emitting type semiconductor optical device, the method comprising:
a first step of forming a first DBR portion of a first conductivity type on a GaAs substrate of the first conductivity type;
a second step of forming an active layer on the first DBR portion, and forming a mesa-shaped first semiconductor layer on the active layer;
a third step of forming a burying layer formed of a single material, by growing undoped GaInP at a region where the first semiconductor layer is not formed on the first. DBR portion; and
a fourth step of forming a second DBR portion on the first semiconductor layer, after formation of the burying layer, wherein
a current confinement portion for supplying current to the active layer is embedded in the first semiconductor layer, and
the burying layer is formed by growing the undoped GaInP at a growth temperature ranging from 500° C. to 600° C.

2. The method for manufacturing a surface-emitting type semiconductor optical device as claimed in claim 1, wherein a resistivity of the undoped GaInP is not lower than 10⁵ Ωcm for a 5 V forward voltage across the surface-emitting type semiconductor optical device.

3. The method for manufacturing a surface-emitting type semiconductor optical device as claimed in claim 1, wherein in the second step, the mesa-shaped first semiconductor layer is formed by forming the current confinement portion on a predetermined region within a first region on the surface of the active layer, embedding the current confinement portion by growing a first layer that is to become the first semiconductor layer, on the surface of the active layer and on the current confinement portion, and by etching, within the first layer, a portion positioned on a second region that is adjacent to the first region on the surface of the active layer, and wherein
in the third step, the burying layer is formed by growing the undoped GaInP on the second region on the surface of the active layer.

4. The method for manufacturing a surface-emitting type semiconductor optical device as claimed in claim 3, wherein
the current confinement portion is formed after forming a first interlayer on the active layer.

5. The method for manufacturing a surface-emitting type semiconductor optical device as claimed in claim 4, wherein
the current confinement portion is a tunnel junction obtained by layering a second semiconductor layer and a third semiconductor layer of mutually different conductivity types;
the current confinement portion is formed by sequentially growing, on the active layer, a second layer that is to become the second semiconductor layer, and a third layer that is to become the third semiconductor layer, and by etching, within the second layer and the third layer, a portion other than the predetermined region; and wherein
the first interlayer is a layer for stopping etching, for forming the current confinement portion.

6. The method for manufacturing a surface-emitting type semiconductor optical device as claimed in claim 1, wherein
in the second step, the mesa-shaped active layer and the first semiconductor layer are formed: by forming the current confinement portion on a predetermined region in the first region on the surface of the active layer; by embedding the current confinement portion by growing a first layer that is to become the first semiconductor layer on the surface of the active layer and on the current confinement portion; and by etching, within the first layer, a portion positioned on a second region that is adjacent to the first region on the surface of the active layer, and etching, within the active layer, a portion outward of the first region and having the second region; and wherein
in the third step, the burying layer is formed by growing the undoped GaInP on a region where the mesa-shaped active layer and the first semiconductor layer are not formed within the surface of the first DBR portion.

7. The method for manufacturing a surface-emitting type semiconductor optical device as claimed in claim 6, wherein in the second step, a second interlayer for stopping the etching is formed on the first DBR portion, whereafter the active layer is formed on the second interlayer.

8. The method for manufacturing a surface-emitting type semiconductor optical device as claimed in claim 6, wherein
the current confinement portion is a tunnel junction obtained by layering a second semiconductor layer and a third semiconductor layer of mutually different conductivity types;
the current confinement portion is formed by sequentially growing, on the active layer, a second layer that is to become the second semiconductor layer, and a third layer that is to become the third semiconductor layer, and by etching, within the second layer and the third layer, a portion other than the predetermined region on the surface of the active layer.

9. The method for manufacturing a surface-emitting type semiconductor optical device as claimed in claim 1, wherein the burying layer is formed by growing the undoped GaInP at a growth temperature ranging from 500° C. to 550° C.

10. The method for manufacturing a surface-emitting type semiconductor optical device as claimed in claim 1, wherein the active layer comprises a III-V compound semiconductor material containing Ga, As and N.

11. The method for manufacturing a surface-emitting type semiconductor optical device as claimed in claim 1, wherein the active layer comprises any among GaInNAs, GaNAs, GaInNAsP, GaNAsP, GaInNAsSb, GaInNAsSbP, GaNAsSbP and GaNAsSb.

12. A surface-emitting type semiconductor optical device, comprising:
a first DBR portion of a first conductivity type provided on a GaAs substrate of the first conductivity type;
an active layer provided on the first DBR portion;
a second DBR portion provided on the active layer;
a mesa-shaped first semiconductor layer, which is provided between the first DBR portion and the second DBR portion, and which has, embedded therein, a current confinement portion for supplying current to the active layer; and
a burying layer, comprising single undoped GaInP, provided between the first DBR portion the second DBR portion, on the side faces of the first semiconductor layer; wherein
the resistivity of the undoped GaInP is not lower than 10⁵ Ωcm.

13. The surface-emitting type semiconductor optical device as claimed in claim 12, wherein the resistivity of the undoped GaInP is not lower than 10⁵ Ωcm for a 5 V forward voltage across the surface-emitting type semiconductor optical device.

14. The surface-emitting type semiconductor optical device as claimed in claim 12, wherein the first semiconductor layer and the burying layer are disposed between the active layer and the second DBR portion, or between the active layer and the first DBR portion.

15. The surface-emitting type semiconductor optical device as claimed in claim 14, further comprising a first interlayer provided between the current confinement portion and the active layer.

16. The surface-emitting type semiconductor optical device as claimed in claim 12, wherein the burying layer is provided on the side faces of the active layer.

17. The surface-emitting type semiconductor optical device as claimed in claim 16, further comprising a second interlayer provided between the first DBR portion and the active layer.

18. The surface-emitting type semiconductor optical device as claimed in claim 12, wherein the current confinement portion is a tunnel junction obtained by layering a second semiconductor layer and a third semiconductor layer of mutually different conductivity types.

19. The surface-emitting type semiconductor optical device as claimed in claim 12, wherein the active layer comprises a III-V compound semiconductor material containing Ga, As and N.

20. The surface-emitting type semiconductor optical device as claimed in claim 12, wherein the active layer comprises any among GaInNAs, GaNAs, GaInNAsP, GaNAsP, GaInNAsSb, GaInNAsSbP, GaNAsSbP and GaNAsSb.
